(19) United States
(12) Patent Application Publication
(10) Pub. No.: US 2014/0001367 A1
(43) Pub. Date: Jan. 2, 2014

(54) RADIOLOGICAL IMAGE DETECTION APPARATUS AND METHOD OF MANUFACTURING THE SAME

(71) Applicant: FUJIFILM Corporation, Tokyo (JP)

(72) Inventors: Akihiro ANZAI, Ashigarakami-gun (JP); Munetaka KATO, Ashigarakami-gun (JP)

(21) Appl. No.: 13/911,888

(22) Filed: Jun. 6, 2013

(30) Foreign Application Priority Data
Jun. 28, 2012 (JP) 2012-145284

(51) Int. Cl. G01T 1/20; H01L 31/0232

(52) U.S. Cl. CPC G01T 1/2006; H01L 31/02322
USPC 250/366; 438/69

(57) ABSTRACT

A ghost is reduced while improving the sensitivity. A scintillator has a plurality of columnar crystals formed of thallium-activated cesium iodide, and converts X-rays into visible light and emits the visible light from the distal end of the columnar crystal. The photoelectric conversion panel has a plurality of photodiodes formed of amorphous silicon to generate electric charges by detecting the visible light emitted from the scintillator. Assuming that the maximum emission intensity of the scintillator is I₁, a wavelength at which the maximum emission intensity is obtained is W_{P}, and the emission intensity at a wavelength of 400 nm is I₂, I₂/I₁≧0.1 and 540 nm≦W_{P}<570 nm are satisfied.

### BACKGROUND OF THE INVENTION

1. Field of the Invention

The present invention relates to a radiological image detection apparatus that detects a radiological image and a method of manufacturing the same.

2. Description of the Related Art

In recent years, in the medical field, a radiation detection apparatus that detects a radiation (for example, X-rays), which is emitted from a radiation source toward an imaging region of a patient and is transmitted through the imaging region, and converts the radiation into electric charges and generates image data indicating a radiological image of the imaging region based on the electric charges is used to perform diagnostic imaging. There are a direct conversion type radiation detection apparatus, which directly converts a radiation into electric charges, and an indirect conversion type radiation detection apparatus, which converts a radiation into visible light first and converts the visible light into electric charges.

The indirect conversion type radiological image detection apparatus has a scintillator (phosphor layer) that converts a radiation into visible light and a photoelectric conversion panel that detects visible light and converts the visible light into electric charges. Cesium iodide (Csl) or gadolinium oxide sulfur (GOS) is used for the scintillator.

In the case of cesium iodide, the manufacturing cost is high compared with GOS. However, since cesium iodide has high conversion efficiency from a radiation to visible light and has a columnar crystal structure, the SN ratio of image data is improved by the light guide effect. Accordingly, cesium iodide is especially used as a scintillator of a high-end radiological image detection apparatus. However, since luminous efficiency is low with only cesium iodide, an improvement in luminous efficiency is achieved by adding an activator, such as thallium (Tl), to acquire thallium-activated cesium iodide (CsI:Tl).

However, if a scintillator is formed of thallium-activated cesium iodide, luminous efficiency is improved, but there is a problem in that the transmittance of visible light of the scintillator is reduced by the addition of thallium and the scintillator absorbs emitted light by itself. For this reason, improving the light transmittance by performing heat treatment in the air atmosphere after forming a scintillator has been proposed (refer to JP2009-47577A).

### SUMMARY OF THE INVENTION

However, although the sensitivity of a radiological image detection apparatus having a scintillator manufactured using a manufacturing method disclosed in JP2009-47577A is enhanced by the improvement in the light transmittance of the scintillator, the generation of a residual image called a ghost becomes a problem. JP2009-47577A does not disclose a method of reducing the ghost while improving the sensitivity.

It is an object of the present invention to provide a radiological image detection apparatus capable of improving the sensitivity and reducing the ghost and a method of manufacturing the same.

In order to solve the above-described problem, a radiological image detection apparatus of the present invention includes: a scintillator that is formed of thallium-activated cesium iodide and that converts a radiation into visible light and emits the visible light; and a photoelectric conversion panel in which a plurality of photoelectric conversion elements, each of which is formed of amorphous silicon to generate electric charges by detecting the visible light emitted from the scintillator, are arrayed. Assuming that a maximum emission intensity of the scintillator is I₁, a wavelength at which the maximum emission intensity is obtained is W_{P}, and an emission intensity at a wavelength of 400 nm is I₂, I₂/I₁≧0.1 and 540 nm≦W_{P}≦570 nm are satisfied.

In addition, it is preferable that a molar ratio of thallium to cesium in the scintillator be equal to or greater than 0.007. In this case, it is preferable that the scintillator be formed by co-deposition of cesium iodide and thallium iodide.

In addition, it is preferable that the scintillator be formed by performing heat treatment at a temperature of 150° C. or higher.

In addition, it is preferable that the photoelectric conversion panel be disposed so as to be closer to an incidence side of a radiation than the scintillator is.

In addition, it is preferable that the scintillator have a plurality of columnar crystals and convert a radiation into visible light and emit the visible light from a distal end of the columnar crystal and that the photoelectric conversion panel be disposed so as to face the distal end.

In addition, it is preferable to further include a surface protective film that covers a surface of the scintillator, and it is preferable that the distal end of the columnar crystal face the photoelectric conversion panel with the surface protective film interposed therebetween.

A method of manufacturing a radiological image detection apparatus of the present invention includes: a scintillator forming step of forming a scintillator, which converts a radiation into visible light and emits the visible light, by depositing thallium-activated cesium iodide, in which a molar ratio of thallium to cesium is equal to or greater than 0.007, on a support substrate; a heat treatment step of performing heat treatment of the scintillator at a temperature of 150° C. or higher; and a bonding step of bonding a photoelectric conversion panel, in which a plurality of photoelectric conversion elements each of which is formed of amorphous silicon to generate electric charges by detecting visible light are arrayed, to the scintillator.

In addition, in the scintillator forming step, it is preferable to perform co-deposition of cesium iodide and thallium iodide on the support substrate.

In addition, it is preferable to further include a surface protective film forming step of forming a surface protective film that covers a surface of the scintillator. In the bonding step, it is preferable to bond the scintillator to the photoelectric conversion panel with the surface protective film interposed therebetween.

In addition, it is preferable that the surface protective film forming step be performed after the heat treatment step.

According to the radiological image detection apparatus of the present invention, it is possible to reduce the ghost and improve the sensitivity by setting I₂/I₁≧0.1 and 540 nm≦W_{P}≦570 nm to be satisfied assuming that the maximum emission intensity of the scintillator is I₁, a wavelength at which the maximum emission intensity is obtained is W_{P}, and the emission intensity at the wavelength of 400 nm is I₂.

### BRIEF DESCRIPTION OF THE DRAWINGS

FIG. 1 is a partially broken perspective view of an X-ray image detection apparatus.

FIG. 2 is a schematic cross-sectional view of the X-ray image detection apparatus.

FIG. 3 is a schematic cross-sectional view showing the detailed configuration of a scintillator.

FIG. 4 is a circuit diagram showing the configuration of an element section of a photoelectric conversion panel.

FIG. 5 is a graph showing the spectral sensitivity characteristics of amorphous silicon.

FIG. 6 is a graph showing the emission spectrum of a scintillator.

FIG. 7 is a graph showing the emission spectrums of scintillators in first to third examples.

FIG. 8 is a graph showing the emission spectrums of scintillators in first to third comparative examples.

FIG. 9 is a graph showing the emission spectrums of scintillators in fourth to sixth comparative examples.

### DESCRIPTION OF THE PREFERRED EMBODIMENTS

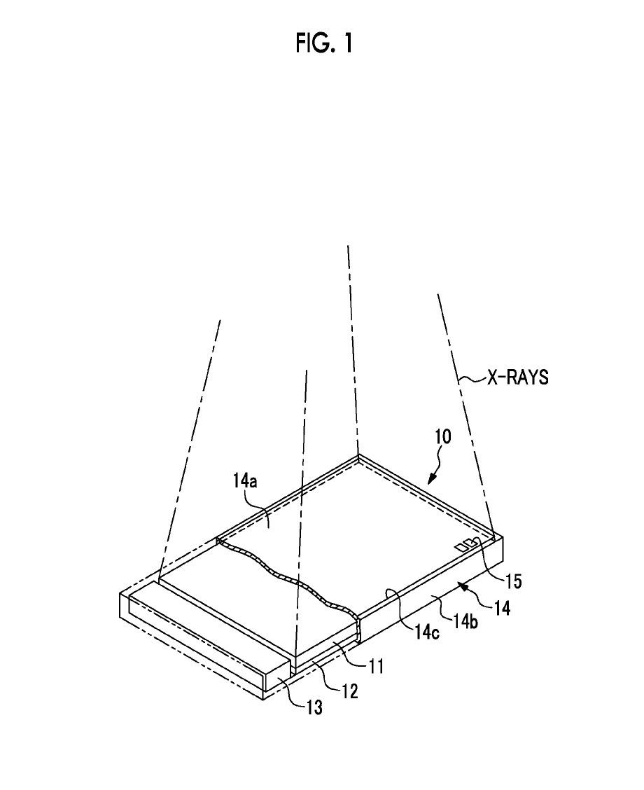

In FIG. 1, an X-ray image detection apparatus 10 is configured to include a flat panel detector (FPD) 11, a base 12, an electric circuit unit 13, and a housing 14 in which these are housed. The housing 14 has a top plate 14a and a flat and box-shaped main body 14b.

The top plate 14a seals an opening 14c formed in an upper portion of the main body 14b. The upper surface of the top plate 14a is an irradiation surface irradiated with X-rays that are emitted from an X-ray generator (not shown) and are transmitted through an imaging region of the subject (patient). For this reason, the top plate 14a is formed of carbon or the like having high X-ray transparency. The main body 14b is formed of ABS resin or the like.

Since the X-ray image detection apparatus 10 is portable similar to the conventional X-ray film cassette and can be used in place of the X-ray film cassette, the X-ray image detection apparatus 10 is called an electronic cassette.

In the housing 14, the FPD 11 and the base 12 are disposed in order from the top plate 14a side. The base 12 is fixed to the main body 14b of the housing 14. The FPD 11 is attached to the base 12. The electric circuit unit 13 is disposed on one end side along the lateral direction in the housing 14. A microcomputer or a battery (neither is shown in the drawing) is housed in the electric circuit unit 13.

The display unit 15 configured to include a plurality of light emitting diodes (LEDs) is provided in the top plate 14a. Operating states, such as an operating mode (for example, a “ready state” or “under data transmission”) of the X-ray image detection apparatus 10 or the remaining capacity of the battery in the electric circuit unit 13, are displayed on the display unit 15. In addition, the display unit 15 may be formed using light emitting elements other than the LED, a liquid crystal display, an organic EL display, or the like.

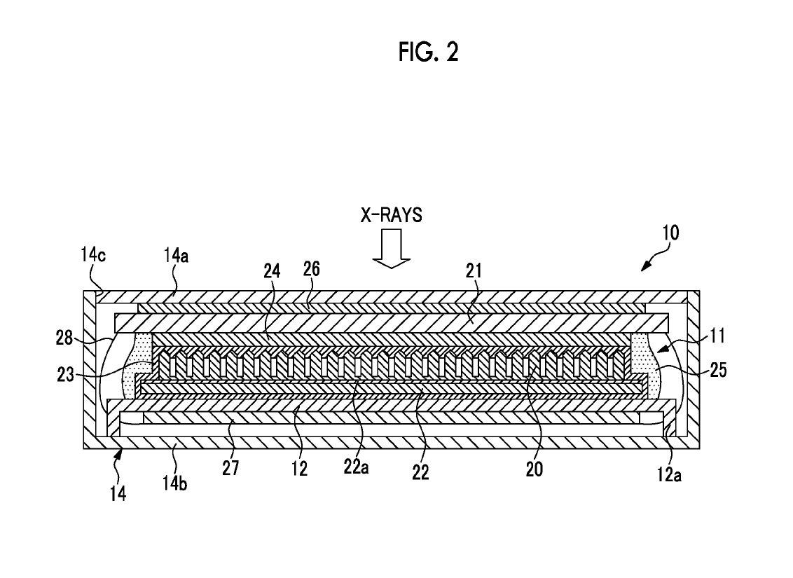

In FIG. 2, the FPD 11 has a scintillator 20 and a photoelectric conversion panel 21. The scintillator 20 is formed by depositing thallium-activated cesium iodide (CsI:Tl) on a support substrate 22, and has a columnar structure. For example, the support substrate 22 is formed of aluminum of about 300 μm in thickness. A substrate protective film 22a is formed on the surface of the support substrate 22 on which the scintillator 20 is formed. For example, the substrate protective film 22a is formed of poly-para-xylene of about 10 μm in thickness. More specifically, parylene C (product name of Nippon Parylene Co. Ltd.; “parylene” is a registered trademark) is used as this poly-para-xylene.

In order to protect the scintillator 20 against moisture, a surface protective film 23 is formed on the entire surface of the scintillator 20 and the support substrate 22 exposed to the outside. For example, the surface protective film 23 is formed of poly-para-xylene of about 20 μm in thickness. More specifically, parylene C (product name of Nippon Parylene Co. Ltd.; “parylene” is a registered trademark) is used as this poly-para-xylene. The refractive index of the scintillator 20 is 1.81, and the refractive index of each of the substrate protective film 22a and the surface protective film 23 is 1.64.

The photoelectric conversion panel 21 is disposed on the top plate 14a side of the scintillator 20, and the photoelectric conversion panel 21 and the scintillator 20 are bonded to each other with an adhesive layer 24 interposed therebetween. The adhesive layer 24 is formed of transparent resin (for example, acrylic resin) to visible light, and has a thickness of about 30 μm, for example. In addition, side portions of the scintillator 20, the support substrate 22, and the adhesive layer 24 are covered by an end sealing material 25. The end sealing material 25 is formed of UV-curable resin. In addition, the photoelectric conversion panel 21 is bonded to the top plate 14a with an adhesive layer 26 interposed therebetween.

The base 12 is fixed to the bottom surface of the main body 14b through leg portions 12a. An electronic substrate 27 to perform driving, signal processing, and the like of the photoelectric conversion panel 21 is fixed to the surface of the base 12 not facing the scintillator 20. The electronic substrate 27 and the photoelectric conversion panel 21 are electrically connected to each other through a flexible cable 28.

The scintillator 20 generates visible light by absorbing X-rays that are transmitted through an imaging region and emitted to the top plate 14a and are then incident after being transmitted through the top plate 14a, the adhesive layer 26, the photoelectric conversion panel 21, the adhesive layer 24, and the surface protective film 23. The visible light generated by the scintillator 20 is incident on the photoelectric conversion panel 21 after being transmitted through the surface protective film 23 and the adhesive layer 24. The photoelectric conversion panel 21 converts the incident visible light into electric charges, and generates image data indicating a radiological image based on the electric charges.

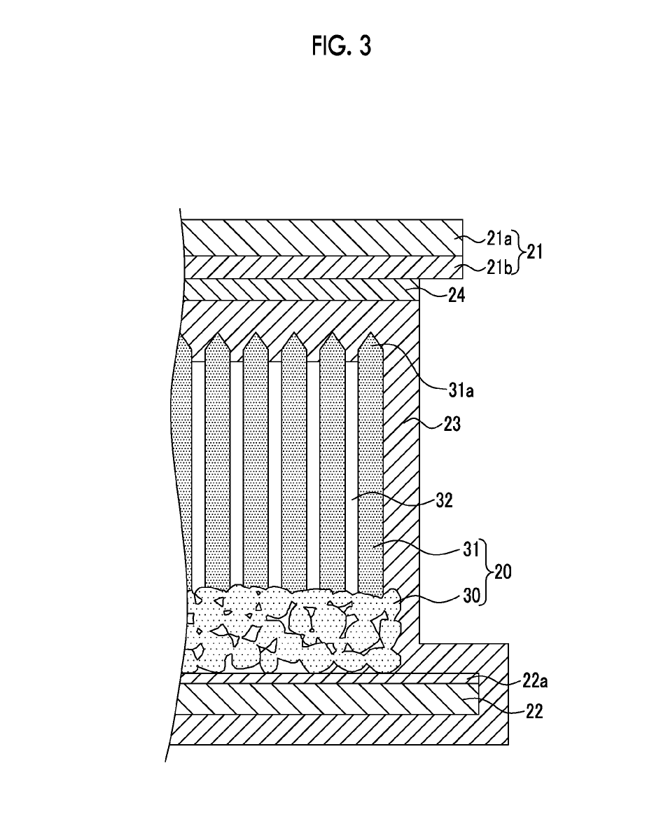

In FIG. 3, the scintillator 20 is configured to include a non-columnar crystal 30 and a columnar crystal 31. The non-columnar crystal 30 has a particle shape, and is formed on the entire support substrate 22. The columnar crystal 31 is formed on the non-columnar crystal 30 by crystal growth with the non-columnar crystal 30 as a base. The plurality of columnar crystals 31 are formed on the non-columnar crystal 30, and are separated from each other with an air layer 32 interposed therebetween. The diameter of the columnar crystal 31 is approximately uniform (about 6 μm) along the longitudinal direction.

Since X-rays are incident on the scintillator 20 from the photoelectric conversion panel 21 side, the generation of visible light within the scintillator 20 mainly occurs on the photoelectric conversion panel 21 side of the columnar crystal 31. The visible light generated in the scintillator 20 propagates through the columnar crystal 31 toward the photoelectric conversion panel 21 by the light guide effect of the columnar crystal 31, and is emitted from a distal end 31a toward the photoelectric conversion panel 21. The distal end 31a has an approximately conical shape, and the angle of the apex is an acute angle (for example, 40° to 80°).

The visible light generated in the columnar crystal 31 also propagates toward the support substrate 22 side by the light guide effect. The visible light propagating through the columnar crystal 31 toward the support substrate 22 side reaches the non-columnar crystal 30, and most of the visible light is reflected by the non-columnar crystal 30 and propagates toward the photoelectric conversion panel 21 side. For this reason, there is little loss of the visible light generated in the scintillator 20.

The photoelectric conversion panel 21 is configured to include a glass substrate 21a and an element section 21b formed on the glass substrate 21a. The glass substrate 21a is disposed so as to be closer to the X-ray incidence side than the photoelectric conversion panel 21 is, and has a thickness of 700 μm, for example.

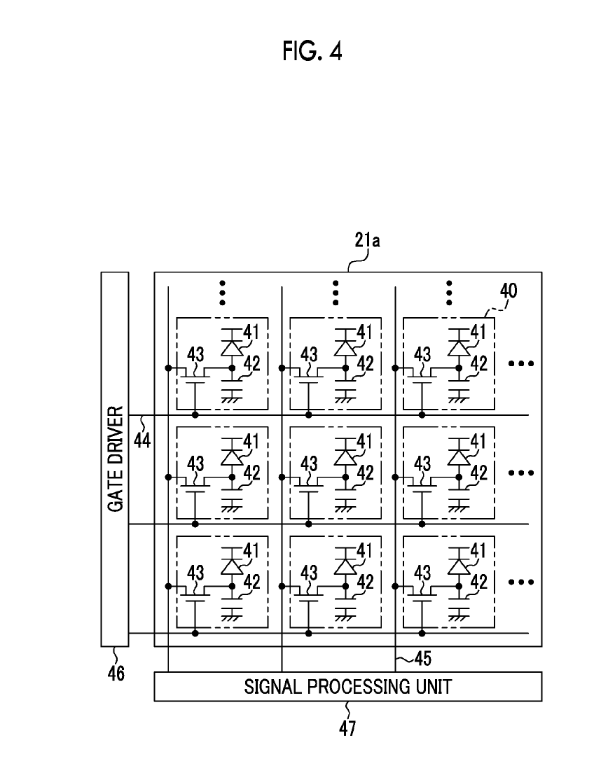

In FIG. 4, the element section 21b is formed by arraying a plurality of pixels 40 in a two-dimensional matrix. Each pixel 40 has a photodiode (PD) 41, a capacitor 42, and a thin film transistor (TFT) 43. The PD 41 is a photoelectric conversion element formed of amorphous silicon, and generates electric charges by absorbing visible light incident from the scintillator 20. The capacitor 42 stores the electric charges generated by the PD 41. The TFT 43 is a switching element for outputting the electric charges stored in the capacitor 42 to the outside of each pixel 40.

Each pixel 40 is connected to a gate line 44 and a data line 45. The gate line 44 extends in a row direction, and the plurality of gate lines 44 are arrayed in a column direction. The data line 45 extends in the column direction, and the plurality of data lines 45 are arrayed in the row direction so as to cross the gate lines 44. The gate line 44 is connected to the gate terminal of the TFT 43. The data line 45 is connected to the drain terminal of the TFT 43.

One end of the gate line 44 is connected to a gate driver 46. One end of the data line 45 is connected to a signal processing unit 47. The gate driver 46 and the signal processing unit 47 are provided in the electronic substrate 27. The gate driver 46 applies a gate driving signal sequentially to each gate line 44, thereby turning on the TFT 43 of the pixel 40 connected to each gate line 44. When the TFT 43 is turned on, electric charges stored in the capacitor 42 are output to the data line 45.

The signal processing unit 47 has an integrating amplifier (not shown) for each data line 45. The electric charges output to the data line 45 are integrated by the integrating amplifier and are converted into a voltage signal. In addition, the signal processing unit 47 has an AID converter (not shown), and converts the voltage signal generated by each integrating amplifier into a digital signal to generate image data.

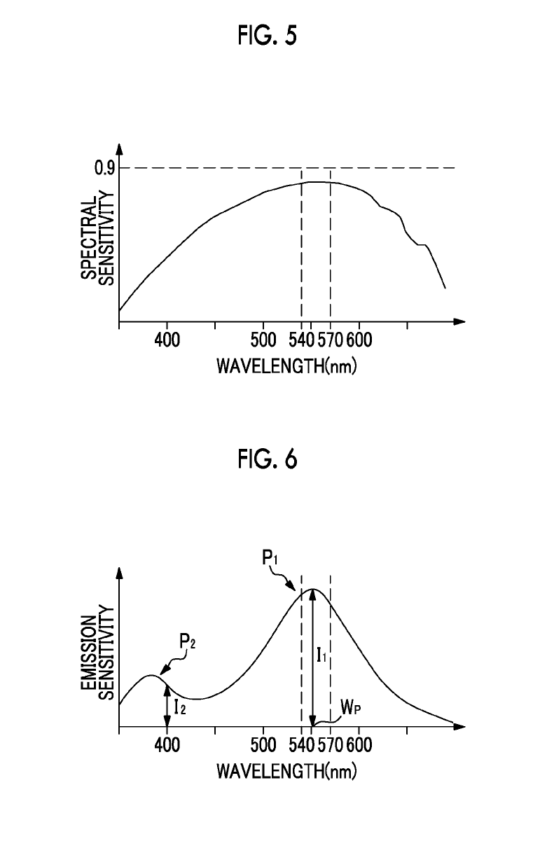

The PD 41 is formed of amorphous silicon. FIG. 5 shows the spectral sensitivity characteristics of amorphous silicon. The maximum sensitivity wavelength of amorphous silicon is near 540 nm to 570 nm.

FIG. 6 shows the emission spectrum of the scintillator 20. In this emission spectrum, a main peak P₁ is generated near the wavelength of 550 nm, and a sub-peak P₂ having a lower emission intensity than the main peak P₁ is generated near the wavelength of 400 nm. The main peak P₁ approximately corresponds to the maximum sensitivity wavelength of the PD 41. The sub-peak P₂ approximately corresponds to a complementary color (blue purple) of the color component (yellow) of the main peak P₁.

The emission intensity I₁ at the main peak P₁ is larger than the emission intensity I₂ at the sub-peak P₂. In the present embodiment, the emission intensity I₂ of the sub-peak P₂ and the emission intensity I₁ of the main peak P₁ satisfy the relationship of I₂/I₁≧0.1. Here, the emission intensity I₁ is set as a maximum intensity in the emission spectrum, and the emission intensity I₂ is set as an emission intensity at the wavelength of 400 nm. When the emission intensity ratio I₂/I₁ is smaller than 0.1, the yellow component in the emission spectrum is larger than the blue purple component of the complementary color. Accordingly, since the color of the scintillator 20 becomes slightly yellow, the light transmittance is reduced. On the other hand, when the emission intensity ratio I₂/I₁≧0.1, the transparency of the scintillator 20 is high. Accordingly, the light transmittance is satisfactory.

The sensitivity of the FPD 11 is expressed as an integral value obtained by integrating the product of the spectral sensitivity characteristic of amorphous silicon and the emission spectrum of the scintillator 20. In the present embodiment, since the maximum peak wavelength W_{P} at the main peak P₁ is in a range of 540 nm to 570 nm to obtain the maximum sensitivity wavelength with the amorphous silicon, the sensitivity of the FPD 11 is improved. In addition, “I₂/I₁≧0.1” and “emission intensity I₂ at the sub-peak P₂ is large” also contribute to the improvement in the sensitivity of the FPD 11.

The maximum peak wavelength W_{P} depends on the deposition rate of cesium iodide (CsI) when manufacturing the scintillator 20, the temperature of the support substrate 22 at the time of deposition, and the amount of added thallium (Tl). The maximum peak wavelength W_{P} is shifted to the long wavelength side as the deposition rate decreases and the amount of thallium increases. In order to set the maximum peak wavelength W_{P} to be in the range of 540 nm to 570 nm, it is preferable to set the molar ratio of thallium to cesium (Cs) (hereinafter, referred to as a “Tl/Cs ratio”) to be equal to or greater than 0.007 (0.7 mol %), for example. More preferably, the Tl/Cs ratio is set to 0.01 (1 mol %).

The addition of thallium to cesium iodide is performed by depositing a mixture of cesium iodide and thallium iodide (TlI) in a predetermined molar ratio on the substrate, as thallium-activated cesium iodide (CsI:Tl), by co-evaporation. In this case, it is preferable to adjust the amount of thallium iodide so that the Tl/Cs ratio becomes equal to or greater than 0.007. By co-evaporation, thallium iodide is activated by ion exchange with cesium. However, there is some remaining in the crystal lattice of cesium iodide in a state of thallium iodide. Since the remaining thallium iodide traps carriers, which may be trapped in a defect (Cs defect or I defect) in the crystal of cesium iodide, and deactivates them without radiation (deactivates them without emitting light), a ghost (residual image) is reduced. That is, if the maximum peak wavelength W_{P} is shifted to the long wavelength side, a state where thallium is easily deactivated is realized. As a result, the ghost reduction efficiency is improved.

Thus, if the Tl/Cs ratio is increased, the maximum peak wavelength W_{P} is shifted to the long wavelength side and a ghost is reduced, but the emission intensity I₂ at the sub-peak P₂ is reduced and the optical transparency of the scintillator 20 is reduced. In order to prevent a decrease in the emission intensity I₂, an annealing process (heat treatment) is performed at a high temperature after forming thallium-activated cesium iodide using the method described above. For example, the annealing process is performed for 2 hours at a temperature of 200° C. in an atmosphere of nitrogen (N₂). Accordingly, since the emission intensity I₂ is increased, the optical transparency can be improved without reducing the sensitivity and the ghost reduction efficiency. In addition, when oxygen is contained in the atmosphere of the annealing process, it degrades the thallium-activated cesium iodide. For this reason, inert nitrogen is used as an atmosphere against the thallium-activated cesium iodide.

Next, a method of manufacturing the FPD 11 will be described. First, the support substrate 22 formed of aluminum is prepared and poly-para-xylene is formed on the support substrate 22 using a vapor deposition method, thereby forming the substrate protective film 22a having a thickness of about 10 μm. Then, the support substrate 22 on which the substrate protective film 22a is formed is put into the chamber of a vapor deposition apparatus (not shown), and thallium-activated cesium iodide having a thickness of about 650 μm is deposited on the substrate protective film 22a by performing co-deposition with a material in which cesium iodide and thallium iodide are mixed. In this case, the amount of thallium iodide is adjusted so that the Tl/Cs ratio of thallium-activated cesium iodide becomes equal to or greater than 0.007 (preferably 0.01).

Then, the support substrate 22 on which thallium-activated cesium iodide is deposited is taken out from the chamber of the vapor deposition apparatus and put into the heat treatment furnace. In the heat treatment furnace, an annealing process is performed for 2 hours at a temperature of 200° C. in a nitrogen atmosphere. By this annealing process, the state of thallium is optimized as described above, and the moisture absorbed in cesium iodide evaporates. As described above, the scintillator 20 having the emission spectrum described above is completed. In addition, it is preferable that the temperature of the annealing process be equal to or higher than 150° C.

Then, the support substrate 22 on which the scintillator 20 is formed is taken out from the heat treatment furnace and poly-para-xylene is formed on the entire support substrate 22 using a vapor deposition method, thereby forming the surface protective film 23 having a thickness of about 20 μm.

Then, the adhesive layer 24 is formed on the surface of the photoelectric conversion panel 21 on the element section 21b side, and the photoelectric conversion panel 21 and the scintillator 20 are bonded to each other so that the adhesive layer 24 faces the distal end 31a of the columnar crystal 31 of the scintillator 20 with the surface protective film 23 interposed therebetween. Finally, UV-curable resin is formed so as to cover the side portions of the scintillator 20, the support substrate 22, and the adhesive layer 24 and is cured by UV irradiation, thereby forming the end sealing material 25. As described above, the FPD 11 is completed.

In addition, the annealing process may be performed after forming the surface protective film 23. However, since the cesium iodide has a property of deliquescence due to moisture, it is preferable to evaporate the moisture by performing the annealing process before forming the surface protective film 23 and then cover the scintillator 20 with the surface protective film 23 for moisture prevention as described above.

Next, the operation in the present embodiment will be described. In order to capture a radiological image using the X-ray image detection apparatus 10, the radiographer (for example, a radiology technician) inserts the X-ray image detection apparatus 10 between the imaging region of the subject and the base (not shown) such that the top plate 14a faces the imaging region, and performs positioning.

After this positioning is completed, the radiographer gives an instruction to start radiographing by operating the console (not shown). In response to this instruction, X-rays are emitted from the X-ray generator (not shown), and the top plate 14a of the X-ray image detection apparatus 10 is irradiated with X-rays transmitted through the imaging region. The X-rays emitted to the top plate 14a are incident on the scintillator 20 after being transmitted through the top plate 14a, the adhesive layer 26, the photoelectric conversion panel 21, the adhesive layer 24, and the surface protective film 23.

The scintillator 20 generates visible light by absorbing the incident X-rays. The generation of visible light within the scintillator 20 mainly occurs on the top plate 14a side in the columnar crystal 31. The light generated in the columnar crystal 31 propagates through each columnar crystal 31, is emitted from the distal end 31a, is transmitted through the surface protective film 23 and the adhesive layer 24, and is incident on the element section 21b of the photoelectric conversion panel 21.

The visible light incident on the element section 21b is converted into electric charges for each pixel 40, and is output to the signal processing unit 47. The signal processing unit 47 converts each electric charge into a voltage signal, and converts the voltage signal into a digital signal to generate image data indicating a radiological image. The image data is transmitted to the console wirelessly or by cable, and an image based on the image data is displayed on a monitor (not shown) connected to the console.

### EXAMPLES

Hereinafter, the present invention will be specifically described through examples. However, the present invention is not limited to these examples.

### First Example

Hereinafter, a first example of the scintillator of the present invention will be described. A surface protective film having a thickness of about 10 μm was formed by performing vapor deposition of poly-para-xylene on a support substrate formed of aluminum. This support substrate was put into the chamber of a vapor deposition apparatus, and thallium-activated cesium iodide (scintillator) having a thickness of about 650 μm was deposited on the substrate protective film by performing co-deposition with a material in which cesium iodide and thallium iodide were mixed. In this case, the amount of thallium iodide was adjusted so that the Tl/Cs ratio became 0.01.

Then, the support substrate was taken out from the chamber and was put into the heat treatment furnace, and an annealing process was performed for 2 hours at a temperature of 200° C. in a nitrogen atmosphere. Then, the support substrate was taken out from the heat treatment furnace and vapor deposition of poly-para-xylene on the entire support substrate formed with a scintillator was performed, thereby forming a surface protective film having a thickness of about 20 μm.

Whether the Tl/Cs ratio was a predetermined value was checked by dissolving the formed scintillator in a few grams of water and quantifying the amount using an inductively coupled plasma method.

### Second Example

As a second example, a scintillator was manufactured as in the first example. In this case, the temperature of the annealing process was 150° C. (processing time was 2 hours).

### Third Example

As a third example, a scintillator was formed as in the first example. In this case, the amount of thallium iodide was adjusted so that the Tl/Cs ratio became 0.007.

Next, comparative examples for characteristic comparison with the scintillator of the present invention will be given.

### First Comparative Example

As a first comparative example, a scintillator was formed as in the first example. In this case, the temperature of the annealing process was 60° C. (processing time was 2 hours).

### Second Comparative Example

As a second comparative example, a scintillator was formed as in the first example. In this case, the annealing process was not performed.

### Third Comparative Example

As a third comparative example, a scintillator was formed as in the first example. In this case, the amount of thallium iodide was adjusted so that the Tl/Cs ratio became 0.007 and the annealing process was not performed.

### Fourth Comparative Example

As a fourth comparative example, a scintillator was formed as in the first example. In this case, the amount of thallium iodide was adjusted so that the Tl/Cs ratio became 0.003.

### Fifth Comparative Example

As a fifth comparative example, a scintillator was formed as in the first example. In this case, the amount of thallium iodide was adjusted so that the Tl/Cs ratio became 0.003 and the annealing process was not performed.

### Sixth Comparative Example

As a sixth comparative example, a scintillator was formed as in the first example. In this case, the amount of thallium iodide was adjusted so that the Tl/Cs ratio became 0.02 and the annealing process was not performed.

Next, the characteristics (emission intensity ratio I₂/I₁, maximum peak wavelength W_{P}, relative sensitivity, and ghost value) of the scintillators formed in the first to third examples and the first to sixth comparative examples were evaluated. As a result, the result shown in Table 1 was obtained.

TABLE 1

| | Tl/Cs | Annealing | | | Relative | Ghost | |
|---|---|---|---|---|---|---|---|
| | ratio | temperature | I₂/I₁ | W_{P} | sensitivity | value | Determination |
| First | 0.01 | 200° C. | 0.22 | 550 nm | 122 | 1.1% | Pass |
| example | | | | | | | |
| Second | 0.01 | 150° C. | 0.14 | 546 nm | 115 | 1.2% | Pass |
| example | | | | | | | |
| Third | 0.007 | 200° C. | 0.15 | 543 nm | 117 | 1.2% | Pass |
| examp | | | | | | | |
| First | 0.01 | 60° C. | F 0.07 | 543 nm | F 111 | 1.2% | Fail |
| comparative | | | | | | | |
| example | | | | | | | |
| Second | 0.01 | None | F 0.04 | 554 nm | F 100 | 1.5% | Fail |
| comparative | | | | | | | |
| example | | | | | | | |
| Third | 0.007 | None | F 0.08 | 550 nm | F 108 | F 1.8% | Fail |
| comparative | | | | | | | |
| example | | | | | | | |
| Fourth | 0.003 | 200° C. | 0.3 | F 525 nm | 130 | F 1.7% | Fail |
| comparative | | | | | | | |
| example | | | | | | | |
| Fifth | 0.003 | None | 0.18 | F 531 nm | F 113 | F 2.2% | Fail |
| comparative | | | | | | | |
| example | | | | | | | |
| Sixth | 0.02 | None | F 0.01 | F 573 nm | F 91 | 1.0% | Fail |
| comparative | | | | | | | |
| example | | | | | | | |

### (Characteristic Evaluation Method)

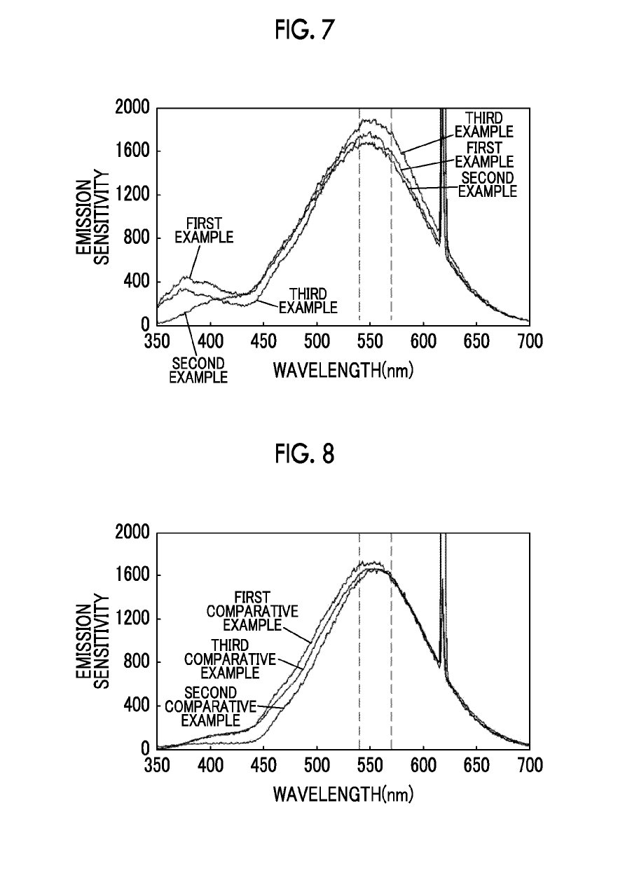

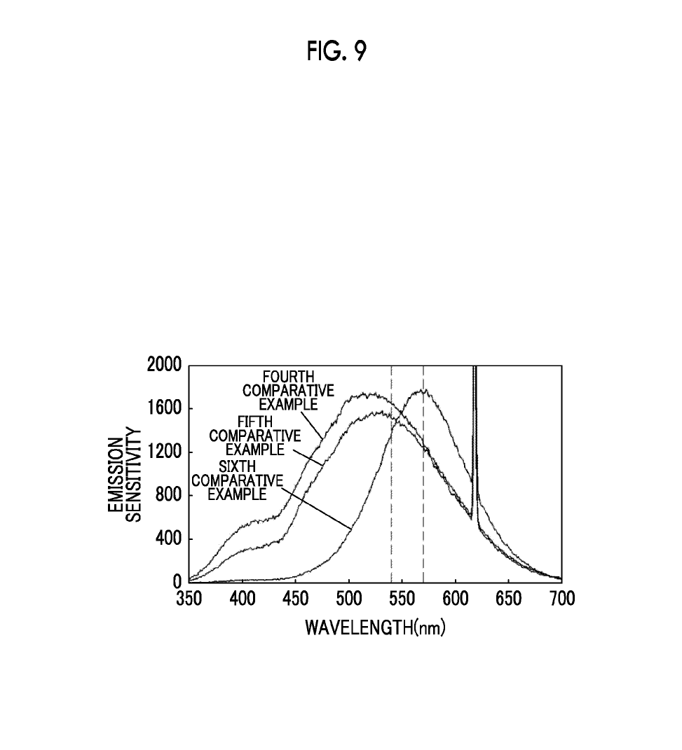

The emission spectrum of the scintillator was acquired by excitation light having a wavelength of 310 nm using an emission spectrophotometer (Hitachi-F4500), and the emission intensity ratio I₂/I₁ was calculated from this emission spectrum. In addition, the maximum peak wavelength W_{P} was calculated based on this emission spectrum. In addition, since the disturbance noise due to the measurement system occurs near the wavelength of 620 nm in the emission spectrum, data near the wavelength of 620 nm was not evaluated. FIG. 7 shows the emission spectrums of the scintillators in the first to third examples. FIGS. 8 and 9 show the emission spectrums of the scintillators in the first to sixth comparative examples.

For the relative sensitivity, the sensitivity was measured with the radiation quality of X-rays under the RQA5 conditions of IEC standards and the imaging dose as 1 mR in a state where the scintillator was placed in the FPD, and the sensitivity when the Tl/Cs ratio was 0.01 and the annealing process was not perfoitned (second comparative example) was expressed as 100. Here, the sensitivity is detected quantum efficiency (DQE).

For the measurement of ghost values, X-rays with an imaging dose of 400 mR were first emitted to a part of the FPD with the radiation quality under the RQA5 conditions of IEC standards, and X-rays with an imaging dose of 5 mR were emitted to the entire FPD when 120 s passed from the X-ray irradiation. Then, the sensitivity A of a region irradiated with the first X-rays with an imaging dose of 400 mR and the sensitivity B of a region that was not irradiated with these X-rays were measured, and the calculated value of {(A/B)−1}×100 (%) was set to the ghost value.

### (Evaluation Criteria)

The emission intensity ratio I₂/I₁ was assumed to be acceptable (pass) when it was equal to or greater than 0.1. The maximum peak wavelength W_{P} was assumed to be acceptable (pass) when it was within the range of 540 nm to 570 nm. The relative sensitivity was assumed to be acceptable when it was equal to or greater than 115. The ghost value was assumed to be acceptable when it was equal to or less than 1.5%.

In the first to third examples, all of the characteristic values were acceptable, and both the sensitivity and the ghost value satisfied the evaluation criteria. On the other hand, in the first to sixth comparative examples, some characteristic values were not acceptable (fail), and the sensitivity or the ghost value did not satisfy the evaluation criteria. Thus, it is possible to reduce the ghost and improve the sensitivity by setting I₂/I₁≧0.1 and 540 nm≦W_{P}≦570 nm to be satisfied.

In addition, although the photoelectric conversion panel 21 and the scintillator 20 are disposed in this order from the X-ray incidence side in the embodiment described above, the scintillator 20 and the photoelectric conversion panel 21 may be disposed in this order from the X-ray incidence side on the contrary.

In addition, although the present invention is applied to the electronic cassette, which is a portable radiological image detection apparatus, in the embodiment described above, the present invention may also be applied to a standing or sitting type radiological image detection apparatus, a mammographic apparatus, and the like.

What is claimed is:

1. A radiological image detection apparatus comprising:
a scintillator that is formed of thallium-activated cesium iodide and that converts a radiation into visible light and emits the visible light; and
a photoelectric conversion panel in which a plurality of photoelectric conversion elements, each of which is formed of amorphous silicon to generate electric charges by detecting the visible light emitted from the scintillator, are arrayed,
wherein, assuming that a maximum emission intensity of the scintillator is I₁, a wavelength at which the maximum emission intensity is obtained is W_{P}, and an emission intensity at a wavelength of 400 nm is I₂, I₂/I₁≧0.1 and 540 nm≦W_{P}≦570 nm are satisfied.

2. The radiological image detection apparatus according to claim 1,
wherein a molar ratio of thallium to cesium in the scintillator is equal to or greater than 0.007.

3. The radiological image detection apparatus according to claim 2,
wherein the scintillator is formed by co-deposition of cesium iodide and thallium iodide.

4. The radiological image detection apparatus according to claim 1,
wherein the scintillator is formed by performing heat treatment at a temperature of 150° C. or higher.

5. The radiological image detection apparatus according to claim 2,
wherein the scintillator is formed by performing heat treatment at a temperature of 150° C. or higher.

6. The radiological image detection apparatus according to claim 1,
wherein the photoelectric conversion panel is disposed so as to be closer to an incidence side of a radiation than the scintillator is.

7. The radiological image detection apparatus according to claim 2,
wherein the photoelectric conversion panel is disposed so as to be closer to an incidence side of a radiation than the scintillator is.

8. The radiological image detection apparatus according to claim 3,
wherein the photoelectric conversion panel is disposed so as to be closer to an incidence side of a radiation than the scintillator is.

9. The radiological image detection apparatus according to claim 4,
wherein the photoelectric conversion panel is disposed so as to be closer to an incidence side of a radiation than the scintillator is.

10. The radiological image detection apparatus according to claim 5,
wherein the photoelectric conversion panel is disposed so as to be closer to an incidence side of a radiation than the scintillator is.

11. The radiological image detection apparatus according to claim 6,
wherein the scintillator has a plurality of columnar crystals, and converts a radiation into visible light and emits the visible light from a distal end of the columnar crystal, and
the photoelectric conversion panel is disposed so as to face the distal end.

12. The radiological image detection apparatus according to claim 7,
wherein the scintillator has a plurality of columnar crystals, and converts a radiation into visible light and emits the visible light from a distal end of the columnar crystal, and
the photoelectric conversion panel is disposed so as to face the distal end.

13. The radiological image detection apparatus according to claim 8,
wherein the scintillator has a plurality of columnar crystals, and converts a radiation into visible light and emits the visible light from a distal end of the columnar crystal, and
the photoelectric conversion panel is disposed so as to face the distal end.

14. The radiological image detection apparatus according to claim 9,
wherein the scintillator has a plurality of columnar crystals, and converts a radiation into visible light and emits the visible light from a distal end of the columnar crystal, and the photoelectric conversion panel is disposed so as to face the distal end.

15. The radiological image detection apparatus according to claim 10,
wherein the scintillator has a plurality of columnar crystals, and converts a radiation into visible light and emits the visible light from a distal end of the columnar crystal, and
the photoelectric conversion panel is disposed so as to face the distal end.

16. The radiological image detection apparatus according to claim 11, further comprising:
a surface protective film that covers a surface of the scintillator,
wherein the distal end faces the photoelectric conversion panel with the surface protective film interposed between the distal end and the photoelectric conversion panel.

17. A method of manufacturing the radiological image detection apparatus according to claim 1, comprising:
a scintillator forming step of forming a scintillator, which converts a radiation into visible light and emits the visible light, by depositing thallium-activated cesium iodide, in which a molar ratio of thallium to cesium is equal to or greater than 0.007, on a support substrate;
a heat treatment step of performing heat treatment of the scintillator at a temperature of 150° C. or higher; and
a bonding step of bonding a photoelectric conversion panel, in which a plurality of photoelectric conversion elements each of which is formed of amorphous silicon to generate electric charges by detecting visible light are arrayed, to the scintillator.

18. The method of manufacturing a radiological image detection apparatus according to claim 17,
wherein, in the scintillator forming step, co-deposition of cesium iodide and thallium iodide is performed on the support substrate.

19. The method of manufacturing a radiological image detection apparatus according to claim 17, further comprising:
a surface protective film forming step of forming a surface protective film that covers a surface of the scintillator,
wherein, in the bonding step, the scintillator is bonded to the photoelectric conversion panel with the surface protective film interposed between the scintillator and the photoelectric conversion panel.

20. The method of manufacturing a radiological image detection apparatus according to claim 19,
wherein the surface protective film forming step is performed after the heat treatment step.
